(19) United States
(12) Patent Application Publication
(10) Pub. No.: US 2008/0265356 A1
(43) Pub. Date: Oct. 30, 2008

(54) CHIP SIZE IMAGE SENSING CHIP PACKAGE

(76) Inventors: Jin-Chyuan Biar, Hsinchu City (TW); Chih-Kung Huang, Hsinchu City (TW)

Correspondence Address: BROWDY AND NEIMARK, P.L.L.C.;624 NINTH STREET, NW, SUITE 300, WASHINGTON, DC, 20001-5303, US

(21) Appl. No.: 12/110,501

(22) Filed: Apr. 28, 2008

(30) Foreign Application Priority Data
Apr. 27, 2007 (TW) 96115115
Sep. 29, 2007 (TW) 96136641

(51) Int. Cl. H01L 31/0203

(52) U.S. Cl. 257/434; 257/E31.11

(57) ABSTRACT

An image sensing chip package includes an image sensing chip having an image sensor disposed on a circuit side thereof that includes electrical conductive pads. A glue layer is applied to the circuit side and around the image sensor. A flexible film wraps the chip in such a way that an inner surface of the film faces the circuit side of the chip, an opening thereof corresponds to the image sensor, an area of the inner surface near the edges of the opening attaches to the glue layer, an inner end of each of conductors disposed on the inner surface of said film bonds to each of the electrical conductive pads, and an outer end of each of the conductors is exposed to connect with other electrical elements. A light transparent member is disposed on an outer surface of the film to seal the opening of the film.

### BACKGROUND OF THE INVENTION

1. Field of the Invention

This invention relates generally to image sensing chip packages, more particularly, to a chip size image sensing chip package.

2. Description of the Related Art

The conventional image sensing chip package, as shown in FIG. 1, generally has a substrate 1, an image sensing chip 2, a frame 3 and a light transparent glass 4. Several electrical conductive pads 5 are formed on the upper surface of the substrate 1. The frame 3 is adhered to the substrate 1 using a first glue layer 6. The image sensing chip 2 is mounted to the substrate 1 and has an image sensor 7. The image sensing chip 2 uses metal wires 8 to connect electrical conductive pads 5 by means of wire bonding, thereby achieving electric connection between the image sensing chip 2 and the substrate 1. The light transparent glass 4 seals and covers on the substrate 1 by using a second glue layer 9.

As the capabilities of image sensing products continue to expand, while the demand for smaller and more lightweight products expands, a need continues for image sensing packages that are relatively small, thin and lightweight compared to existing packages. However, the prior art chip package just introduced has so many elements to contribute to the size and weight thereof so that it is too bulky and heavy to match the nowadays need.

Thus, in nowadays, there is desired an improved image sensing chip package which is relatively small, thin and lightweight compared to existing packages.

### SUMMARY OF THE INVENTION

The present invention is directed to an improved image sensing chip package.

In an aspect of the present invention, a chip size image sensing chip package provided by the present invention comprises an image sensing chip, a glue layer, a flexible film and a light transparent member. The chip includes a circuit side and a back side, an image sensor disposed on the circuit side, a plurality of electrical conductive pads formed around the image sensor. The glue layer is disposed on the circuit side around the image sensor. The flexible film includes an inner surface, an outer surface, an opening, and a pattern of conductors formed on the inner surface. Each of the conductors has an inner end near the edges of the opening and an outer end extending outwardly from the inner end. The film wraps the chip in such a way that the inner surface of the film faces the circuit side of the chip, the opening corresponds to the image sensor, an area of the inner surface near the edges of the opening attaches to the glue layer, the inner end of each of the conductors of the film bonds to each of the electrical conductive pads of the chip, and the outer end of each of the conductors of the film is opened so as to connect with other electrical elements. The light transparent member is disposed on the outer surface of the film in such a way that the opening of the film is sealed thereby.

In another aspect of the present invention, a chip size image sensing chip package provided by the present invention comprises an image sensing chip, a glue layer, a flexible film and a light transparent member. The image sensing chip includes a circuit side and a back side, an image sensor disposed on the circuit side, a plurality of electrical conductive pads formed around the image sensor. The glue layer is disposed on the circuit side around the image sensor. The flexible film includes an inner surface, an outer surface, an opening, and a pattern of conductors formed on the outer surface. Each of the conductors has an inner end near the edges of the opening and an outer end extending outwardly from the inner end. The film wraps the chip in such a way that the inner surface of the film faces the circuit side of the chip, the opening corresponds to the image sensor, an area of the inner surface near the edges of the opening covers on the glue layer, the inner end of each of the conductors of the film bonds to each of electrical conductive pads of the chip, and the outer end of each of the conductors of the film is opened so as to connect with other electrical elements. The light transparent member is disposed on the outer surface of the film in such a way that the opening of the film is sealed by the light transparent member and the glue layer.

### BRIEF DESCRIPTION OF THE DRAWINGS

The various objects and advantages of the present invention will be more readily understood from the following detailed description when read in conjunction with the appended drawing, in which:

FIG. 1 is a cross sectional view showing a conventional image sensor chip package;

FIG. 2 is a schematic perspective view of an image sensing chip package according to a first preferred embodiment of the present invention;

FIG. 3 is a schematic perspective view of an image sensing chip of the image sensing chip package shown in FIG. 2;

FIG. 4 is a plan view of a flexible film of the image sensing chip package shown in FIG. 2;

FIG. 5 is a partly schematic perspective view of the image sensing chip package shown in FIG. 2;

FIG. 6 is a cross-sectional view taken along line 6-6 of FIG. 2;

FIG. 7 is a cross-sectional view taken along line 7-7 of FIG. 2;

FIG. 8 is a cross-sectional view of an image sensing chip package according to a second preferred embodiment of the present invention;

FIG. 9 is a cross-sectional view of an image sensing package chip according to a third preferred embodiment of the present invention; and

FIG. 10 is a cross-sectional view of an image sensing package according to a fourth preferred embodiment of the present invention.

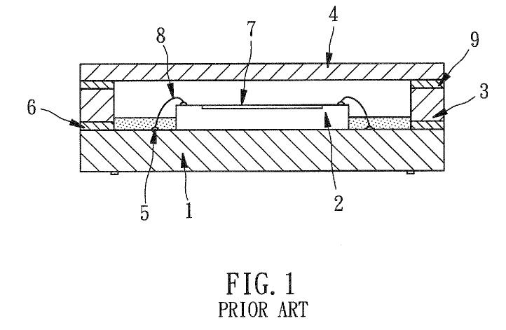

### DETAILED DESCRIPTION OF THE INVENTION

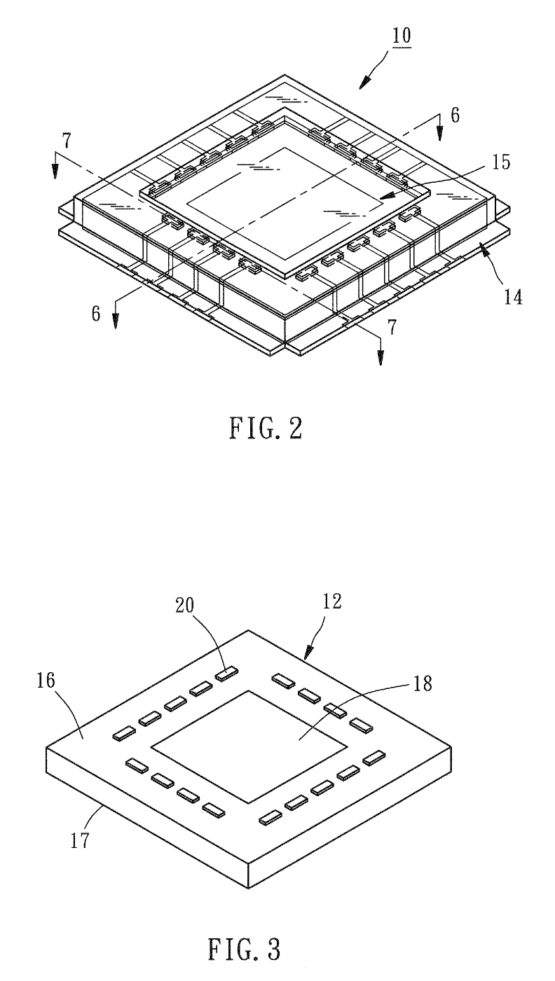

Referring firstly to FIGS. 2 to 7, a chip size image sensing chip package 10 according to a first preferred embodiment of the present invention comprises an image sensing chip 12, a flexible film 14 wrapping chip 12, and a light transparent glass 15.

The image sensing chip 12, as shown in FIG. 3, includes a circuit side 16 and a back side 17. An image sensor 18 is disposed on the centre area of circuit side 16. A plurality of electrical conductive pads 20 are formed on the edges of circuit side 16.

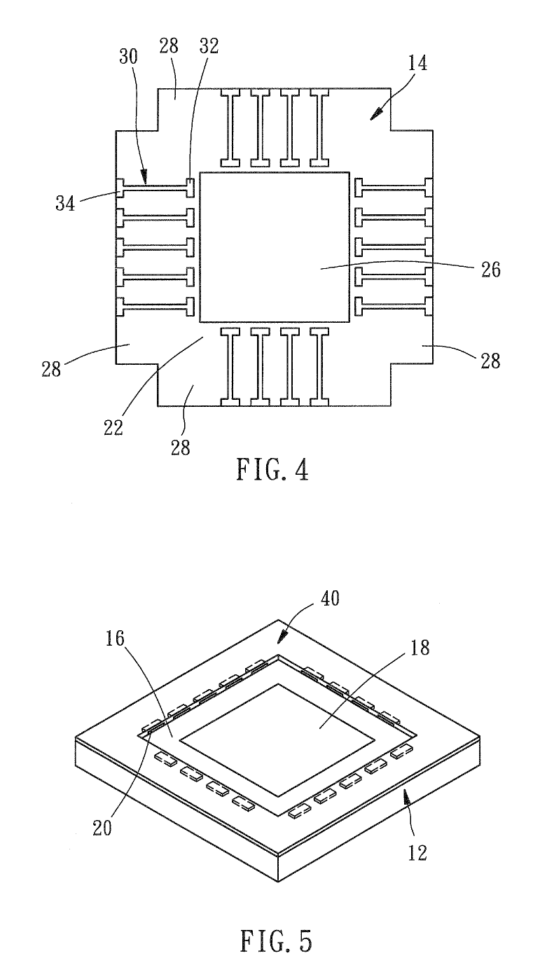

The flexible film 14 is made of plastic materials, such as PE (polyethylene), PVC (polyvinyl chloride), PC (polycarbonate) or any other suitable films. The film 14 in this embodiment, as shown in FIG. 4, is square-shaped and includes an inner surface 22, an outer surface 24, a centre opening 26, four foldable sides 28, and a pattern of conductors 30 formed on the inner surface 22. Each of conductors 30 has an inner end 32 near the edges of opening 26 and an outer end 34 extending outwardly from inner end 32.

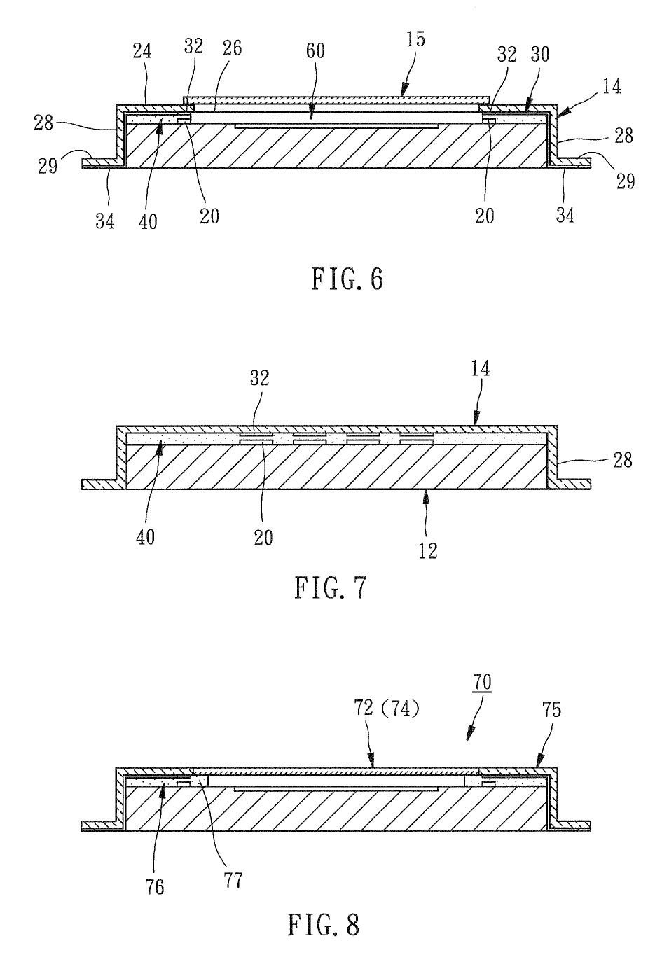

A glue layer 40 is disposed on circuit side 16 and around image sensor 18, as shown in FIG. 5, so as to form a sealed space 60 when chip 12 is wrapped by film 14 and opening 26 is covered by glass 15, as shown in FIG. 6. In this embodiment, glue layer 40 is an anisotropic conductive glue.

In the packaging process, glue layer 40 is firstly adhered to chip 12 in such a way that it is around image sensor 18 and on an upper side of each of electrical conductive pads 20, as shown in FIG. 5, and then film 14 wraps chip 12 in such a way that the inner surface 22 thereof faces circuit side 16 of chip 12, opening 26 thereof corresponds to image sensor 18, inner end 32 of each of conductors 30 respectively corresponds to each of electrical conductive pads 20, each of foldable sides 28 is folded respectively to adhere on each of lateral sides of chip 12. And a free end 29 of each of foldable sides 28 is outwardly folded so that outer end 34 of each of conductors 30 is exposed to outside to connect with other electrical elements.

After the wrapping process, film 14, glue layer 40 and chip 12 are heated and pressed together for a period of time. Due to the feature of anisotropic conductive glue, inner end 32 of each of conductors 30 can electrically contact with each of electrical conductive pads 20 but without creating short circuits between these contacts. And in the same time, sealed space 60, as shown in FIG. 6, is formed by glass 15 and glue layer 40.

Referring secondly to FIG. 8, it is a sectional view illustrating an image sensing chip package 70 according to a second embodiment of the invention. The difference between image sensing package 70 and image sensing package 10 is that the glass 72 of the package 70 is smaller than the opening 74 of the film 75, and glue layer 76 has a shoulder 77 around opening 74 so that edges of the glass 72 is attached to shoulder 77 to seal opening 74.

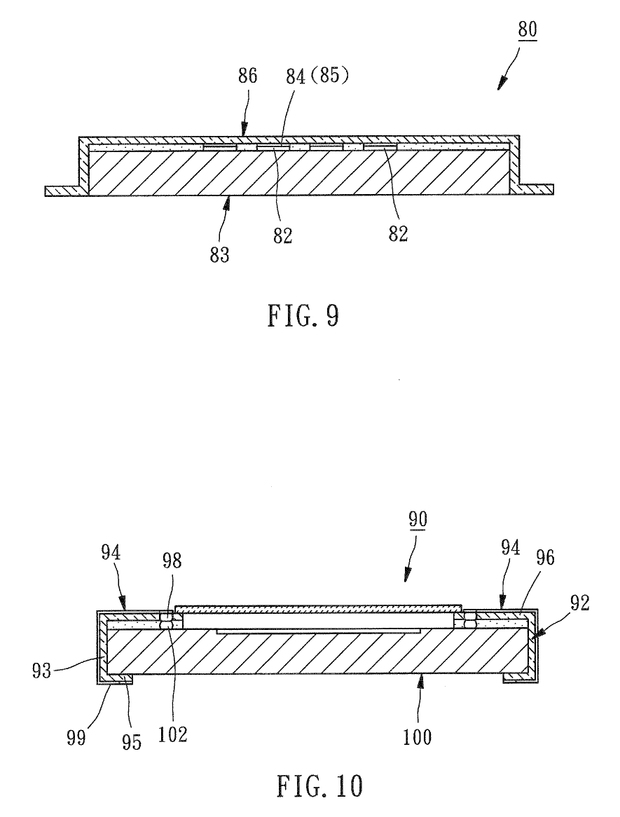

FIG. 9 is a sectional view illustrating an image sensing chip package according to a third embodiment of the invention, wherein elements of which are common with those of image sensing chip package 10 as shown in the FIG. 2. The difference between the third embodiment chip package 80 and chip package 10 is that each of electrical conductive pads 82 of chip 83 of chip package 80 is directly bonded to inner end 84 of each of conductors 85 of film 86.

Referring lastly to FIG. 10, it is a sectional view illustrating an image sensing chip package 90 according to a fourth embodiment of the invention. The difference between image sensing package 90 and image sensing package 10 is that the former has a flexible film 92 with a pattern of conductors 94 formed on an outer surface 96 thereof. Each of conductors 94 has an inner end 98 and an outer end 99. When the flexible film 92 wraps the chip 100, inner end 98 of each of conductors 94 pierces through film 92 so as to bond to each of electrical conductive pads 102 of chip 100. Film 92 also has four foldable sides 93, but outer end 95 thereof is respectively inwardly folded so that outer end 99 of each of conductors 94 is exposed to outside to connect with other electrical elements.

As described above, for having the flexible film wrapping the chip to substitute for the substrate and frame of the prior art chip package, the image sensing chip package provided by the present invention can be smaller, thinner and lighter than any existing packages.

What is claimed is:

1. A chip size image sensing chip package, comprising:
an image sensing chip including a circuit side and a back side, an image sensor disposed on said circuit side, a plurality of electrical conductive pads formed around said image sensor;
a glue layer disposed on said circuit side and around said image sensor;
a flexible film including an inner surface, an outer surface, an opening, and a pattern of conductors formed on said inner surface, each of said conductors having an inner end near the edges of said opening and an outer end extending outwardly from said inner end, and
said film wrapping said chip in such a way that said inner surface of said film faces said circuit side of said chip, said opening corresponds to said image sensor, an area of said inner surface near the edges of said opening attaches to said glue layer, said inner end of each of said conductors of said film bonds to each of said electrical conductive pads of said chip, and said outer end of each of said conductors of said film is opened so as to connect with other electrical elements; and
a light transparent member disposed on said outer surface of said film in such a way that said opening of said film is sealed thereby.

2. The image sensing chip package of claim 1, wherein said glue layer is an anisotropic conductive glue.

3. The image sensing chip package of claim 2, wherein said anisotropic conductive is disposed around said image sensor of said chip and on an upper side of each of said electrical conductive pads thereof.

4. The image sensing chip package of claim 1, wherein said film comprises a plurality of foldable sides, each of said sides extending outwardly from the edges of said opening of said film.

5. The image sensing chip package of claim 4, wherein each of said sides of said film is folded to attach to a lateral side of said chip.

6. The image sensing chip package of claim 5, wherein each of said sides of said film has a free end folded outwardly so that the outer end of each of said conductors is exposed to outside to connect with other electrical elements.

7. A chip size image sensing chip package, comprising:
an image sensing chip including a circuit side and a back side, an image sensor disposed on said circuit side, a plurality of electrical conductive pads formed around said image sensor;
a glue layer disposed on said circuit side and around said image sensor;
a flexible film including an inner surface, an outer surface, an opening, and a pattern of conductors formed on said outer surface, each of said conductors having an inner end near the edges of said opening and an outer end extending outwardly from said inner end, and
said film wrapping said chip in such a way that said inner surface of said film faces said circuit side of said chip, said opening corresponds to said image sensor, an area of said inner surface near the edges of said opening covers on said glue layer, said inner end of each of said conductors of said film bonds to each of electrical conductive pads of said chip, and said outer end of each of said conductors of said film is opened so as to connect with other electrical elements; and
a light transparent member disposed on said outer surface of said film in such a way that said opening of said film is sealed by said light transparent member and said glue layer.

8. The image sensing chip package of claim 7, wherein said glue layer is an anisotropic conductive glue.

9. The image sensing chip package of claim 8, wherein said anisotropic conductive is disposed around said image sensor of said chip and on an upper side of each of said electrical conductive pads thereof.

10. The image sensing chip package of claim 7, wherein said inner end of each of conductors pierces through said film so as to bond to each of said electrical conductive pads of said chip.

11. The image sensing chip package of claim 10, wherein said film comprises a plurality of foldable sides, each of said sides extending outwardly from the edges of said opening of said film.

12. The image sensing chip package of claim 11, wherein each of said sides of said film is folded to attach to a lateral side of said chip.

13. The image sensing chip package of claim 12, wherein each of said sides of said film has a free end inwardly folded so that the outer end of each of said conductors is exposed to outside to connect with other electrical elements.
